(19) United States
(12) Patent Application Publication
(10) Pub. No.: US 2019/0044774 A1
(43) Pub. Date: Feb. 7, 2019

(54) CLOCK SYNCHRONIZER TO SYNCHRONIZE A DEVICE CLOCK WITH A CLOCK OF A REMOTE DEVICE

(71) Applicant: PANTHRONICS AG, Graz (AT)

(72) Inventors: Jan CROLS, Oud-Heverlee (BE); Tomaz FELICIJAN, Graz (AT); Jakob JONGSMA, Graz (AT); Michael PIEBER, Kumberg (AT); Hamzeh NASSAR, Graz (AT)

(21) Appl. No.: 16/075,330

(22) PCT Filed: Jan. 27, 2017
(86) PCT No.: PCT/EP2017/051775

§ 371 Date: Aug. 3, 2018

(30) Foreign Application Priority Data
Feb. 5, 2016 (EP) 16154369.9

(51) Int. Cl. H04L 27/26; H03L 7/18; H04W 56/00; H03L 7/087; H03L 7/099; H04L 7/00

(52) U.S. Cl. CPC H04L 27/266; H03L 7/18; H04W 56/0015; G04F 10/005; H03L 7/087; H03L 7/0992; H04L 7/0079; H04W 56/0035

(57) ABSTRACT

A device (1)) with an antenna that receives a target carrier signal (3) from a remote target (2) and transmits a device carrier signal (6) modulated with data to communicate data between the device (1) and the target (2), which device (1) comprises: clock extraction means (4) to extract a target clock (5) from the target carrier signal (3); driver means (9) to generate the device carrier signal (6) from a device clock (8); synchronization means (7) to synchronize the frequency and phase of the device clock (8) with the target clock (5), wherein that the synchronization means (7) comprise: time measurement means (10) to measure the phase difference between the target clock (5) and the device clock (8) or an internal device clock (33) related to the device clock (8) and to provide a phase information (φ1,φ2,φ3); measurement control means (20) to initiate a first time measurement that results in a first phase information (φ) and to initiate a second time measurement a fixed time period (ΔT) after the first time measurement that results in a second phase information (φ2); frequency correction means (11) to correct the frequency of the device clock (8) and/or the internal device clock (33) to the frequency of the target clock (5) based on an evaluation of the first phase information (φ) and second phase information (φ2) by evaluation means (21); which measurement control means (20) are built to initiate a third time measurement after the frequency correction of the device clock (8) and/or the internal device clock (33) that results in a third phase information (φ3) evaluated by the evaluation means (21) and corrected by phase correction means (22) which correct the phase of the device clock (8) to the phase of the target clock (5).

### FIELD OF THE INVENTION

The present invention relates to a device with an antenna that receives a target carrier signal from a remote target and transmits a device carrier signal modulated with data to communicate data between the device and the target, which device comprises clock extraction means to extract a target clock from the target carrier signal and driver means to generate the device carrier signal from a device clock and synchronization means to synchronize the frequency and phase of the device clock with the target clock.

The present invention relates to a method to synchronize the frequency and phase of a device clock within a device with a target clock of a remote target which target clock within the device is derived from a target carrier signal received from the target with an antenna of the device.

### BACKGROUND OF THE INVENTION

Wireless communication is used in a variety of fields and devices as for instance to identify products with a tag attached to the product or for a communication between a smart card and a reader or target for a payment application. Many such applications use standards like ISO/IEC18000-3 or ISO/IEC 14.443 Type A and B or ISO15.693 or ECMA-340 13,56 MHz Near Field Communication (NFC) that define protocols and types of modulation used to transmit information between the tag or smart card and the target. In most of these communications the target generates an electromagnetic field by sending a target carrier signal and the passive smart card or tag uses this electromagnetic field to generate power to start its internal processor and to initiate communication with the target using the electromagnetic field generated by the target.

NFC furthermore enables that a device (reader or target) simulates a smart card which actively sends data using its own electromagnetic field by sending a modulated device carrier signal. In such a case the device (reader or target that simulates a smart card) needs to synchronize or correct the frequency and phase of the device carrier signal with the target carrier signal to enable correct demodulation of the modulated data within the target.

EP 2 843 840 A1 discloses synchronization means to synchronize a device clock within the device with a reader clock of a remote reader which reader clock within the device is derived from the reader carrier signal received from the reader with an antenna of the device. These state of the art synchronization means comprise a first phase lock loop circuit that receives the reader carrier signal and generates a control signal. These synchronization means furthermore comprise a second phase lock loop circuit that receives a stable reference-oscillation signal and adjusts a fractional divider ratio according to the control signal of the first phase lock loop circuit to provide the device clock.

These synchronization means disclosed in EP 2 843 840 A1 comprise the disadvantage that it takes a relative long locking time until the device clock is synchronized to the reader or target clock. Disturbances during the locking time may influence the results negatively. It is furthermore a disadvantage of the known synchronization means that they need to run continuously what increases the power consumption of the device.

### SUMMARY OF THE INVENTION

It is an objective of the invention to provide a device with synchronizations means and a method to synchronize the frequency and phase of a device clock within the device with a target clock of a remote target that needs only a short time to synchronize and reduces the power consumption of the device.

This objective is achieved with synchronization means that comprise:

time measurement means to measure the phase difference between the target clock and the device clock or an internal device clock related to the device clock to provide a phase information;
measurement control means to initiate a first time measurement that results in a first phase information and to initiate a second time measurement a fixed time period after the first time measurement that results in a second phase information;
frequency correction means to correct the frequency of the device clock and/or the internal device clock to the frequency of the target clock based on an evaluation of the first phase information and second phase information by evaluation means;
which measurement control means are built to initiate a third time measurement after the frequency correction of the device clock and/or the internal device clock that results in a third phase information evaluated by the evaluation means and corrected by phase correction means which correct the phase of the device clock to the phase of the target clock.

This objective is furthermore achieved with a method that comprises the following steps:

measure the phase difference between the target clock and the device clock or an internal device clock related to the device clock and provide a first phase information;
count a fixed number of clocks of an internal clock to wait a fixed time; measure the phase difference between the target clock and the device clock or the internal device clock again and provide a second phase information;
correct the frequency of the device clock and/or the internal device clock to the frequency of the target clock by evaluation of the first phase information and second phase information; measure the phase difference between the target clock and the device clock or the internal device clock again and provide a third phase information;
correct the phase of the device clock to the phase of the target clock by evaluation of the third phase information.

This provides the advantage that only three time measurements to measure phase differences are needed to correct the frequency and phase of the device clock to run synchronal to the frequency and phase of the target clock. This synchronization may be repeated after some time or if some errors are detected within the demodulated data received, but in principle this is a one time synchronization and not a continuous synchronization process like disclosed in prior art. As a result, power consumption within the device is reduced. Furthermore, all these time measurements are processed in the digital domain what increases the accuracy of the synchronization of the device carrier signal with the target carrier signal.

Different embodiments of the invention will be explained. In a simple embodiment there is no internal device clock used and all time measurements are done between the target clock and the device clock, which after synchronization both comprise the same frequency and phase. In another embodiment of the invention an internal device clock is used that may have the same frequency as the target clock or a multiple or split of the target clock, which internal device clock is used for the time measurements. In still another embodiment of the invention disclosed in FIGS. 1 to 4 below an internal device clock is used and the device clock after synchronization by the synchronization means comprises the same phase as the target clock, but its frequency is not identical with the frequency of the target clock.

Synchronization of the frequency of the device clock with the target clock for this embodiment of the invention is meant in that way that the synchronized frequency is a fixed division or multiple of the target clock as will be explained below.

These and other aspects of the invention will be apparent from and elucidated with reference to the embodiments described hereinafter. The person skilled in the art will understand that various embodiments may be combined.

### BRIEF DESCRIPTION OF THE DRAWINGS

FIGS. 1 shows a device with synchronization means to synchronize a device clock with a target clock of a remote target.

FIG. 2 shows a time diagram of the device clock and the target clock and phase information measured with time measurement means of the device shown in FIG. 1.

FIG. 3 shows details of the time measurement means of the device shown in FIG. 1.

FIG. 4 shows a time diagram of clocks and information generated in the device shown in FIG. 1.

### DETAILED DESCRIPTION OF EMBODIMENTS

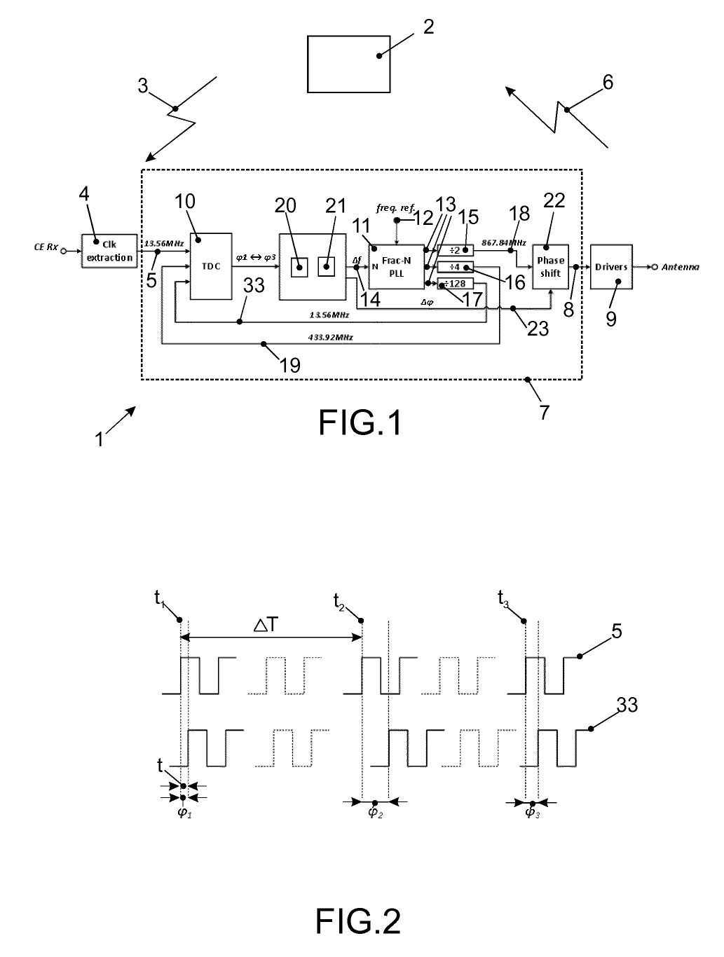

FIG. 1 shows part of a device 1 that is in contactless communication with a target 2 based on ECMA-340 13,56 MHz Near Field Communication (NFC) Standard. Target 2 generates an electromagnetic field by sending a target carrier signal 3 with a frequency of 13,56MHz to communicate with passive smart cards or tags. Device 1 is an active element with its own power source, but simulates a smart card for particular NFC applications.

Device 1 comprises an antenna that receives the target carrier signal 3 from the remote target 2 and clock extraction means 4 to extract a target clock 5 from the target carrier signal 3. To comply with the NFC Standard, device 1 needs to transmit back a device carrier signal 6 with the same 13,56 MHz frequency and phase as the target carrier signal 3, which device carrier signal 6 may be modulated with data to be transmitted from device 1 to target 2. Synchronization of the device carrier signal 6 to the target carrier signal 3 is needed to ensure error-free demodulation and decoding of data transmitted.

Device 1 comprises synchronization means 7 to synchronize the frequency and phase of a device clock 8 with the target clock 5. In the embodiment disclosed the frequency of the device clock 8 after synchronization is not the same or identical as the frequency of the target clock 5, but it is a defined multiple of the 13,56 MHz and in that way synchronized. Elements of the synchronization means 7 and their functionality will be explained in detail based on the FIGS. 1 to 4. Device 1 furthermore comprises driver means 9 to generate the device carrier signal 6 from the device clock 8 that is related to an internal device clock 33 in that way that the frequency of device clock 8 is 867,84 MHz and therefore 64 times higher than the frequency of internal device clock 33 with its 13,56 MHz. Details of driver means 9 are disclosed in an earlier filed patent application about this power amplifier with the application number EP 15199768.1. Driver means 9 use the device clock 8 to generate the 13,56 MHz that are synchronized with the same frequency and phase as the target clock 5. The device carrier signal 6 is used to drive the antenna of device 1 to generate the 13,56 MHz electromagnetic field received in target 2.

Synchronization means 7 comprise time measurement means 10 to measure the phase difference or time difference between the target clock 5 and the internal device clock 33 and to provide a phase information φ. In this embodiment of the invention time measurement means 10 measure the time difference between the target clock 5 and the internal device clock 33. As shown in FIG. 2 time measurement means 10 use the rising edge of the target clock 5 to start the time measurement and the rising edge of the next internal device clock 33 to stop the time measurement. The time measurement results in a measured time t that is equivalent to a phase information φ taking the frequency of 13,56 MHz into account. As an example phase information φ=45° is equivalent to t=9.22 ns. In another embodiment of the invention time measurement means 10 could also use the rising edge of the internal device clock 33 to start the time measurement and the rising edge of the next target clock 5 to stop the time measurement to achieve a measured time t that comprises an equivalent phase information φ. In still another embodiment of the invention the device clock 8 would be provided to time measurement means 10 to measure the phase information φ.

Synchronization means 7 comprise frequency correction means 11 that receive a reference clock 12 from another part of device 1, not shown in FIG. 1, which reference clock 12 comprises a frequency in the range of 9 MHz to 52 MHz. Frequency correction means 11 are realized by a phase lock loop element and provide a high frequency clock 13 of 1,736 GHz corrected with a frequency error 14 to three dividers 15, 16 and 17 that divide the high frequency clock 13 into two internal clocks 18 and 19 and into the internal device clock 33, still without corrected phase, all with lower frequency than the high frequency clock 13. Time measurement means 10 use the internal clock 19 to measure the time difference between the target clock 5 and the internal device clock 33.

Synchronization means 7 furthermore comprise measurement control means 20 to initiate a first time measurement at time instance t₁, shown in FIG. 2 left side, that results in a first phase information φ₁ and to initiate a second time measurement at time instance t₂, shown in the middle of FIG. 2, a fixed time period ΔT after the first time measurement that results in a second phase information φ₂. Synchronization means 7 furthermore comprise evaluation means 21 to evaluate the first phase information φ₁ and the second phase information φ₂ and to provide the frequency error 14 to the correction means 11 to correct the frequency of the internal device clock 33 to the frequency of the target clock 5. Evaluation means 21 are built to calculate the frequency error 14 between the target clock 5 and the internal device clock 33 using the formula: Δf=(φ₂−φ₁)/ΔT . If for instance φ₁=15° and φ₂=225° with ΔT=2.5 ms this results in a frequency error of Δf=233.3 Hz. Frequency correction means 11 are built to correct the frequency of the internal device clock 33 to the frequency of the target clock 5 based on the calculated frequency error 14. This provides the advantage that synchronization means 7 synchronize the frequency of the internal device clock 33 and as a result also of device clock 8 with the target clock 5 with only two time measurements what can be done fast and with only minimal power consumption within device 1.

Measurement control means 20 are furthermore built to initiate a third time measurement at time instance t₃, shown in FIG. 2 right side, after the frequency correction of the internal device clock 33 and of the device clock 8 what measurement results in a third phase information φ₃ . Synchronization means 7 furthermore comprise phase correction means 22 to correct the phase of the device clock 8 to the phase of the target clock 5 with phase correction 23 evaluated based on the third phase information φ₃. This provides the advantage that synchronization means 7 synchronize the phase of the device clock 8 with the target clock 5 with only one time measurement what can be done fast and with only minimal power consumption within device 1.

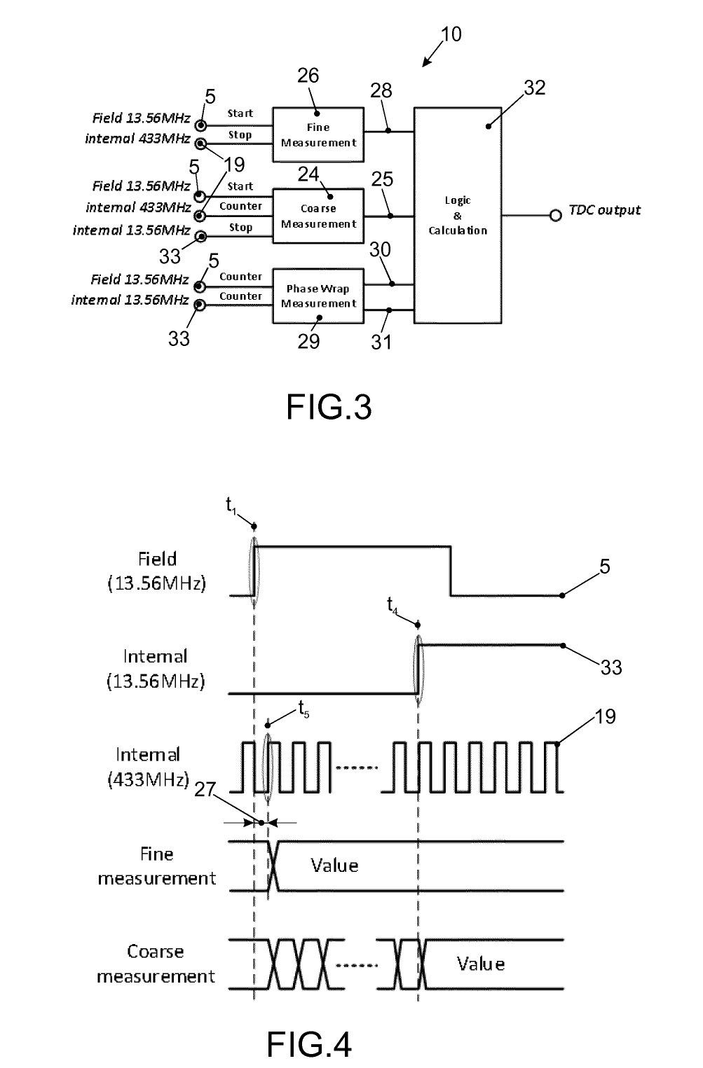

FIG. 3 shows details of time measurement means 10 of the device 1 shown in FIG. 1. FIG. 4 shows a time diagram of clocks and information generated in the device 1 during time measurement with time measurement means 10. Time measurement means 10 comprise coarse measurement means 24 that start a counter that counts with the internal clock 19 at the edge of the target clock 5 at time instance t₁ and that stop the counter at the edge of the internal device clock 33 at time instance t₄ to provide coarse phase information 25. Time measurement means 10 furthermore comprise fine measurement means 26 that measure the time period 27 from the edge of the target clock 5 at time instance t₁ to the next edge of the internal clock 19 at time instance t₅ to provide fine phase information 28. With the frequency of 13,56 MHz of the target clock 5 and the frequency of 433,92 MHz of internal clock 19 fine measurement means 26 have a range of 73,74 ns and a resolution of 0,1 ns. In another embodiment of the invention the range could be e.g. 5 ns with the same resolution of 0,1 ns. Time measurement means 10 are built to evaluate the coarse phase information 25 and the fine phase information 28 to provide the phase information φ. This provides the advantage that time measurement means 10 measures the phase difference very accurate and fast.

Time measurement means 10 furthermore comprise a phase wrap detector 29 that counts the number of edges of the target clock 5 and the number of edges of the internal device clock 33 during the fixed time period ΔT and provides a phase wrap information that comprises a number information 30 of the counted edges of the target clock 5 and a number information 31 of the counted edges of the internal device clock 33. Calculation means 32 of time measurement means 10 compare this number information 30 and 31 and detect a phase wrap. A phase wrap happens if the frequencies of the target clock 5 and the internal device clock 33 are far off and a full period or even several full periods of the clocks have to be taken into account for the evaluation of the measured phase difference. This provides the advantage that time measurement means 10 detect phase wraps and even in such cases evaluate the correct phase information to be used to synchronize the device clock 8 with target clock 5.

It has to be stated that in the embodiment provided time measure means 10 do not use the final synchronized device clock 8 as input to measure the phase difference to the target clock 5 as they use the internal device clock 33 before phase correction processed by phase correction means 22. This is possible as there is no difference for the frequency correction and the phase correction. Using the uncorrected internal device clock 33 for third time measurement will result in the measurement of that uncorrected phase error which will be corrected by phase correction means 22. In another embodiment of the invention device clock 8 could be used for the third time measurement as well.

Device 1 furthermore uses a method to synchronize the frequency and phase of the device clock 8 within the device 1 with the target clock 5 of the remote target 2, which target clock 5 within the device 1 is derived from the target carrier signal 3 received from the target 2 with an antenna of the device 1. This method comprises the following steps:

measure the phase difference between the target clock 5 and the device clock or the internal device clock 33 and provide a first phase information φₗ;
count a fixed number of clocks of an internal clock to wait a fixed time;
measure the phase difference between the target clock 5 and the device clock or the internal device clock 33 again and provide a second phase information φ₂;
correct the frequency of the device clock 8 and/or the internal device clock 33 to the frequency of the target clock 5 by evaluation of the first phase information φ₁ and second phase information φ₂ ;
measure the phase difference between the target clock 5 and the device clock 8 or internal device clock 33 again and provide a third phase information φ₃;
correct the phase of the device clock 8 to the phase of the target clock 5 by evaluation of the third phase information φ₃. This method provides the advantages described above in relation with the device 1.

A device with inventive synchronization means has been described based on an embodiment that complies to the NFC Standard and with a device 1 that simulates a smart card or tag and actively sends data modulated onto a device carrier signal. The inventive concept of synchronization means as describe may be used within any other device that needs to synchronize its clock to the clock of a remote further device. Such concept could also be adopted for other fields including systems that detect movement, location and proximity. Where no second device exists, and the incoming signal is a reflection of the systems own signal, like in radar or motion sensors.

In another embodiment of the invention time measurement means 10 only require fine measurement means 26 to provide phase information cp. This enables a simple solution for time measurement means.

In another embodiment of the invention both the internal device clock and the device clock could be identical and run on a frequency of 13,56 MHz, what means that internal device clock is not needed anymore as separate clock. Synchronization means would in that case synchronize and generate a device clock with exact the same frequency and phase as the target clock and feed this device clock into driver means that directly would use this device clock to generate the device carrier signal.

1. Device with an antenna that receives a target carrier signal from a remote target and transmits a device carrier signal modulated with data to communicate data between the device and the target, which device comprises:
clock extraction means to extract a target clock from the target carrier signal;
driver means to generate the device carrier signal from a device clock;
synchronization means to synchronize the frequency and phase of the device clock with the target clock,
wherein the synchronization means comprise:
time measurement means to measure the phase difference between the target clock and the device clock or an internal device clock related to the device clock and to provide a phase information (φ₁,φ₂, φ₃);
measurement control means to initiate a first time measurement that results in a first phase information (φ₁) and to initiate a second time measurement a fixed time period (ΔT) after the first time measurement that results in a second phase information (φ₂);
frequency correction means to correct the frequency of the device clock and/or the internal device clock to the frequency of the target clock based on an evaluation of the first phase information (φ₁) and second phase information (φ₂) by evaluation means;
which measurement control means are built to initiate a third time measurement after the frequency correction of the device clock and/or the internal device clock that results in a third phase information (φ₃) evaluated by the evaluation means and corrected by phase correction means which correct the phase of the device clock to the phase of the target clock.

2. Device according to claim 1, which comprises clock generation means to generate a an internal clock with a higher frequency than the frequency of the target clock and wherein the time measurement means comprise coarse measurement means that start a counter that counts with the internal clock at an edge of the target clock or of the internal device clock and that stop the counter at the an edge of the internal device clock or the target clock to provide a coarse phase information.

3. Device according to claim 2, wherein the time measurement means comprise fine measurement means that measure the time from an edge of the target clock to the next edge of the internal clock to provide a fine phase information.

4. Device according to claim 3, wherein the time measurement means are built to evaluate the coarse phase information and the fine phase information to provide the phase information (φ₁, φ₂, φ₃).

5. Device according to claim 4, wherein the time measurement means comprise a phase wrap detector that counts the number of edges of the target clock and the number of edges of the internal device clock during the fixed time period (ΔT) and provides a phase wrap information.

6. Device according to claim 5, wherein the time measurement means are built to evaluate the phase wrap information to provide the phase information (φ₁, φ₂, φ₃).

7. Device according to claim 1, wherein the evaluation means are built to calculate a frequency error between the target clock and the device clock or the internal device clock using the formula: Δf=(φ₂−φ₁)/ΔT with φ₁ as first phase information and φ₂ as second phase information and ΔT as fixed time period and which frequency correction means are furthermore built to correct the frequency of the device clock and/or the internal device clock to the frequency of the target clock based on the calculated frequency error.

8. Device according to claim 1, wherein the device simulates a smart card or tag with active data transmission.

9. Method to synchronize the frequency and phase of a device clock within a device with a target clock of a remote target which target clock within the device is derived from a target carrier signal received from the target with an antenna of the device, which method comprises the following steps:
measure the phase difference between the target clock and the device clock or an internal device clock related to the device clock and provide a first phase information (Φ₁);
count a fixed number of clocks of an internal clock to wait a fixed time;
measure the phase difference between the target clock and the device clock or the internal device clock again and provide a second phase information (φ₂);
correct the frequency of the device clock and/or the internal device clock to the frequency of the target clock by evaluation of the first phase information and second phase information (φ₂);
measure the phase difference between the target clock and the device clock internal device clock again and provide a third phase information (φ₃);
correct the phase of the device clock to the phase of the target clock by evaluation of the third phase information (φ₃).

10. Method according to claim 9, wherein the measurement of the phase difference between the target clock and the internal device clock is done with the following steps:
start a counter that counts with the internal clock at an edge of the target clock or of the internal device clock and stop the counter at an edge of the internal device clock or target clock to provide a coarse phase information;
measure the time period from an edge of the target clock to the next edge of the internal device clock to provide a fine phase information;
count the number of edges of the target clock and the number of edges of the internal device clock during the fixed time period (ΔT) and provide a phase wrap information;
evaluate the coarse phase information and the fine phase information and the phase wrap information to provide the phase information (φ₁, φ₂, φ₃).
